(19) United States
(12) Patent Application Publication
(10) Pub. No.: US 2010/0090727 A1
(43) Pub. Date: Apr. 15, 2010

(54) VOLTAGE DETECTION CIRCUIT AND BGR VOLTAGE DETECTION CIRCUIT

(75) Inventors: Ryu Ogiwara, Yokohama-Shi (JP); Daisaburo Takashima, Yokohama-Shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/563,980

(22) Filed: Sep. 21, 2009

(30) Foreign Application Priority Data
Oct. 15, 2008 (JP) 2008-266042

(51) Int. Cl. H03K 5/153; H03K 5/00

(52) U.S. Cl. 327/81; 327/50

(57) ABSTRACT

A voltage detection circuit of the present invention includes an NMOS transistor diode-connected, a gate and a drain thereof being supplied with a power supply voltage, a resistor connected between a source of the NMOS transistor and a ground potential, and a source voltage detection circuit receiving a voltage of the source, wherein an NMOS type transistor is employed as the NMOS transistor, a channel width and a channel length of the NMOS type transistor being set in such a manner that an operating point on a VG-ID curve of the NMOS type transistor may come to a certain point, at the certain point, a drain current of the NMOS type transistor being constant even if the temperature fluctuates.

### CROSS REFERENCE TO RELATED APPLICATIONS

This application is based upon and claims the benefit of priority from the prior Japanese Patent Application No. 2008-266042, filed on Oct. 15, 2008 in Japan, the entire contents of which are incorporated herein by reference.

### BACKGROUND OF THE INVENTION

1. Field of the Invention

The present invention relates to a voltage detection circuit and a BGR voltage detection circuit and, for example, to a voltage detection circuit for use in an SRAM, a DRAM, an EEPROM, an FRAM, etc., necessary to detect the high-speed rise and fall of a power supply.

2. Related Art

Conventionally, a circuit has been proposed in which the drain and the gate of an NMOS transistor are diode-connected, a power supply voltage VDD is connected to the drain side, and its source side is grounded via a current-limiting resistor so that if the potential of the power supply rises at least to a certain desired value, a gate-to-source potential difference of the NMOS transistor may rise at least to a threshold voltage to turn it on and to make a rise in potential of the source received by a downstream-side circuit, thus detecting a rise in potential of the power supply, and if the potential of the power supply falls at least to a certain desired value, the gate-to-source potential difference of the NMOS transistor may fall at least to the threshold voltage to turn it off and to make a fall in potential of the source received by the downstream-side circuit, thus detecting a fall in potential of the power supply.

However, the conventional voltage detection circuits have a problem that a rise in temperature would decrease the threshold voltage and so lower the power supply voltage level to be detected and, in contrast, a fall in temperature would increase the threshold voltage and so raise the power supply voltage level to be detected.

Further, in conventional BGR voltage detection circuits, a BGR voltage output from a Band-Gap-Reference (BGR) circuit would be received by an operational amplifier (O.P.Amp.) to be multiplied by a numeric constant and output as the power supply voltage of the above diode-connected NMOS transistor, thereby detecting whether the BGR circuit is providing a sufficient voltage desired. It is to be noted that such a conventional BGR circuit is known which is described in, for example, a document (BANBA et al. “A CMOS Bandgap Reference Circuit with Sub-1-V Operation” IEEE JOURNAL OF SOLID-STATE CIRCUITS VOL. 34, No. 5, pp. 670-674, MAY 1999).

However, the threshold voltage of the NMOS transistors has a temperature dependency, so that to detect the potential even in the case of a high threshold voltage due to a low temperature, the above constant must be set to a large value, which causes a problem of disadvantages in low-voltage operations.

### SUMMARY OF THE INVENTION

In accordance with one embodiment of the present invention, there is provided a voltage detection circuit including: an NMOS transistor diode-connected, a gate and a drain thereof being supplied with a power supply voltage; a resistor connected between a source of the NMOS transistor and a ground potential; and a source voltage detection circuit receiving a voltage of the source, wherein an NMOS type transistor is employed as the NMOS transistor, a channel width and a channel length of the NMOS type transistor being set in such a manner that an operating point on a VG-ID curve of the NMOS type transistor may come to a certain point, at the certain point, a drain current of the NMOS type transistor being constant even if the temperature fluctuates.

Moreover, in accordance with another embodiment of the present invention, there is provided a voltage detection circuit including: a PMOS transistor diode-connected, a source thereof being supplied with a power supply voltage; a resistor connected between a drain of the PMOS transistor and a ground potential; and a drain voltage detection circuit receiving a voltage of the drain, wherein a PMOS type transistor is employed as the PMOS transistor, a channel width and a channel length of the PMOS type transistor being set in such a manner that an operating point on a VG-ID curve of the PMOS type transistor may come to a certain point, at the certain point, a drain current of the PMOS type transistor being constant even if the temperature fluctuates.

In addition, in accordance with a further embodiment of the present invention, there is provided a BGR voltage detection circuit comprising: a reference voltage generation circuit comprising: a first diode connected between a first node and a ground potential; a first resistor connected between the first node and the ground potential; a second resistor, one end thereof being connected to a second node; a plurality of second diodes connected in parallel, in each of the second diode, one end thereof being connected to the other end of the second resistor and the other end thereof being connected to the ground potential; a third resistor connected between the second node and the ground potential; a first PMOS transistor connected between the first node and a power supply voltage; a second PMOS transistor connected between the second node and the power supply voltage; a third PMOS transistor connected between a third node and the power supply voltage; a fourth resistor connected between the third node and the ground potential; and a first amplifier circuit, an inverting input terminal thereof being supplied with a voltage of the first node, a non-inverting terminal thereof being supplied with a voltage of the second node, and an output terminal thereof being connected to the respective gates of the first, second, and third PMOS transistors, wherein a voltage of the third node is output as a BGR voltage; a second amplifier circuit outputting a power-on output voltage by amplifying the voltage of the first node or the second node; an NMOS transistor diode-connected, a gate and a drain thereof being supplied with the power-on output voltage; a fifth resistor connected between a source of the NMOS transistor and the ground potential; and a source voltage detection circuit receiving a voltage of the source of the NMOS transistor.

### BRIEF DESCRIPTION OF THE DRAWINGS

FIG. 1 is a circuit diagram of a voltage detection circuit of a first comparison example;

FIG. 2 is a graph showing VG-ID characteristics of an NMOS transistor which is used in the voltage detection circuit of the first comparison example;

FIG. 3 is a circuit diagram of a voltage detection circuit according to a first embodiment of the present invention;

FIG. 4 is a graph showing the VG-ID characteristics with respect to three temperatures according to the first embodiment of the present invention;

FIG. 5 is a circuit diagram of a voltage detection circuit according to a second embodiment of the present invention;

FIG. 6 is a graph showing the VG-ID characteristics with respect to three varying mobilities (high, medium, and low mobilities) of a diode-connected NMOS transistor according to the second embodiment of the present invention;

FIG. 7 is a circuit diagram of a BGR voltage detection circuit of a second comparison example;

FIG. 8 is a circuit diagram of an operational amplifier which is used in the BGR voltage detection circuit of FIG. 7;

FIG. 9 shows a BGR voltage detection circuit according to a third embodiment of the present invention;

FIG. 10 is a circuit diagram of a voltage detection circuit according to a modification of the first embodiment of the present invention; and

FIG. 11 is a circuit diagram of a voltage detection circuit according to a modification of the second embodiment of the present invention.

### DETAILED DESCRIPTION OF THE INVENTION

Hereafter, embodiments according to the present invention will be described more specifically with reference to the drawings. Those embodiments will not limit the present invention.

Before describing a first embodiment of the present invention, a voltage detection circuit of a first comparison example the present inventor et al. perceive will be described.

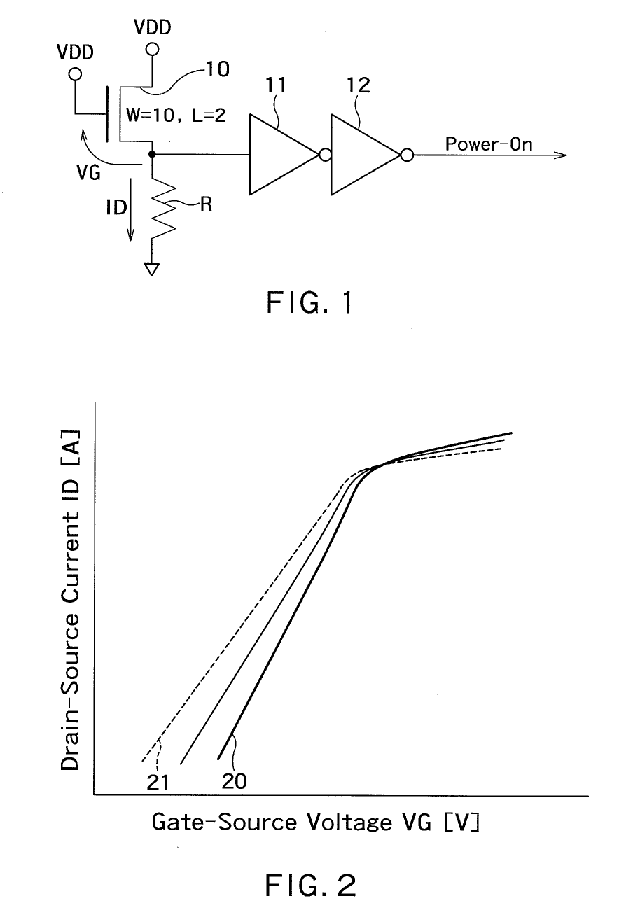

FIG. 1 shows a circuit diagram of the first comparison example. This circuit includes an NMOS transistor 10 whose drain and gate are diode-connected in a constitution that a power supply voltage VDD is connected to the drain side and the source side is grounded via a current limiting resistor R and inverter circuits 11 and 12 (source voltage detection circuit) which receive a potential of the source. In this comparison example, the NMOS transistor 10 has a channel width W of 10 μm and a channel length L of 2 μm.

As can be seen from VG-ID (gate-to-source voltage vs. drain current) characteristics of FIG. 2, as the temperature rises, the threshold voltage decreases so that the power supply voltage level to be detected may fall (curve 21) and, in contrast, as the temperature falls, the threshold voltage increases so that the power supply voltage level to be detected may rise (curve 20).

### First Embodiment

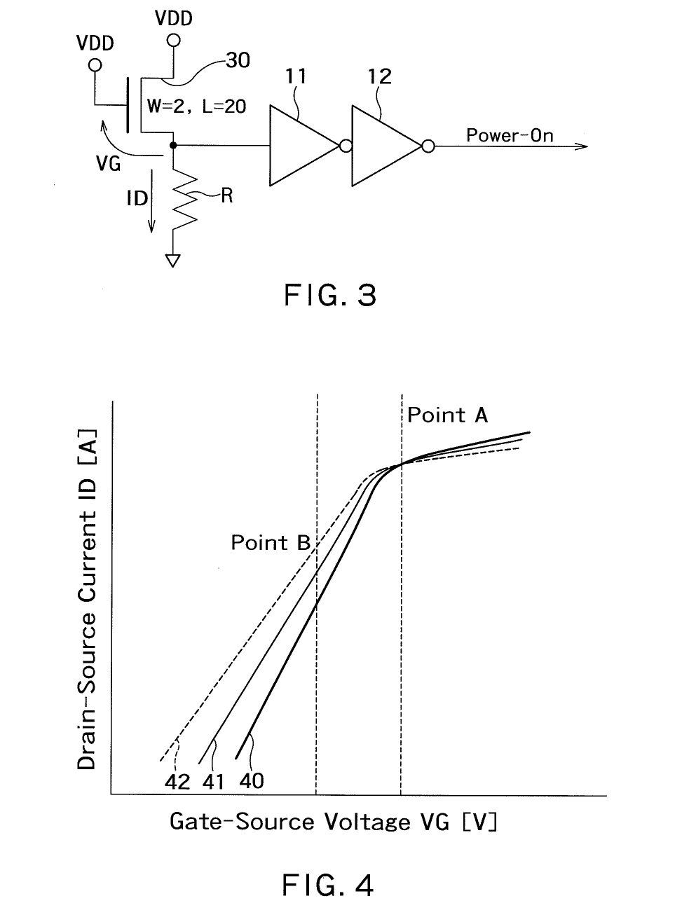

Next, the first embodiment of the present invention will be described with reference to FIGS. 3 and 4. The first embodiment provides a circuit arranged to detect a constant power supply voltage irrespective of temperatures. FIG. 3 shows a circuit configuration in which the ratio of W/L (W and L are the channel width and the channel length of the diode-connected NMOS transistor 30 respectively) is reduced with respect to the comparison example shown of FIG. 1. In the present embodiment, the NMOS transistor 30 has a channel width W of 2 μm and a channel length L of 20 μm. The other circuit configurations are the same as those in the comparison example of FIG. 1, and identical reference numerals are given to the similar components, to omit repetitive description on them.

Furthermore, FIG. 4 is a graph showing the VG-ID characteristics as the function of three temperatures. Curves 40, 41, and 42 show the characteristics at the low temperature, the room temperature, and the high temperature, respectively. From this figure, it is known that where ID is small, the effect of decreasing the threshold voltage with the temperature increasing is strong so that ID may increase, and where ID is large, the effect of decreasing the mobility with the temperature increasing is strong so that ID may decrease.

It is to be noted that at point A in the figure, the effect of decreasing the threshold voltage and the effect of decreasing the mobilities owing to a rise in temperature will be canceled out by each other. Therefore, the point is whether it is possible to control an operating point on the VG-ID curve of the diode-connected NMOS transistor so that it may come to point A.

In contrast to the first comparison example in which W and L have been determined so that the operating point on the VG-ID curve may come to point B in order to provide the weak inversion condition of the NMOS transistor 10, in the present embodiment, the ratio of W/L of the NMOS transistor 30 is made small so that the operating point of the transistor may come to point A.

As described above, according to the present embodiment, it is possible to detect a constant power supply voltage irrespective of the temperatures.

### Second Embodiment

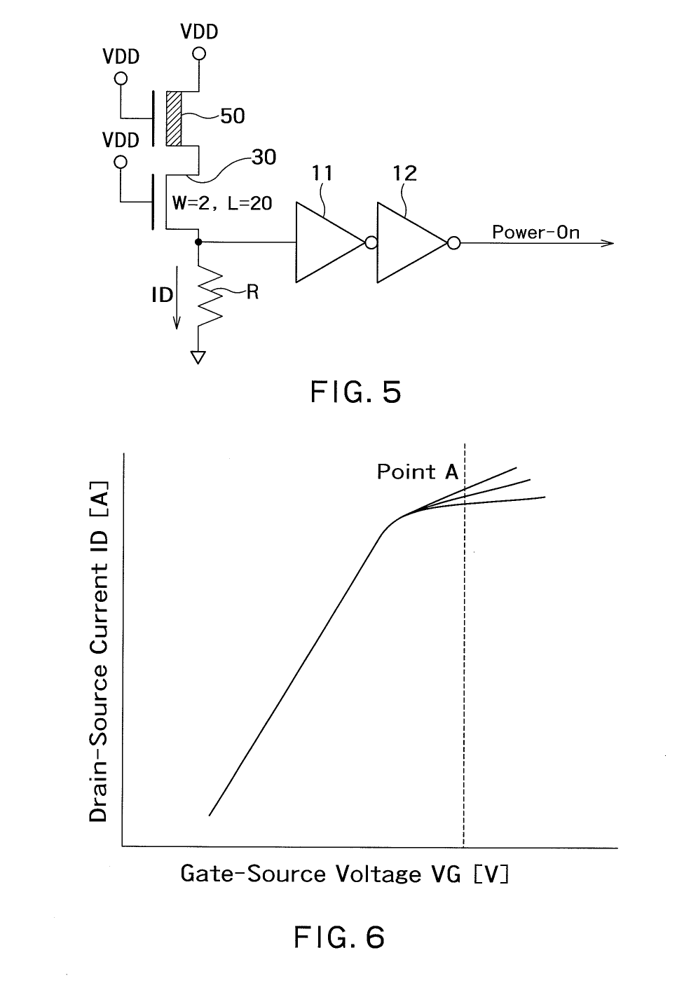

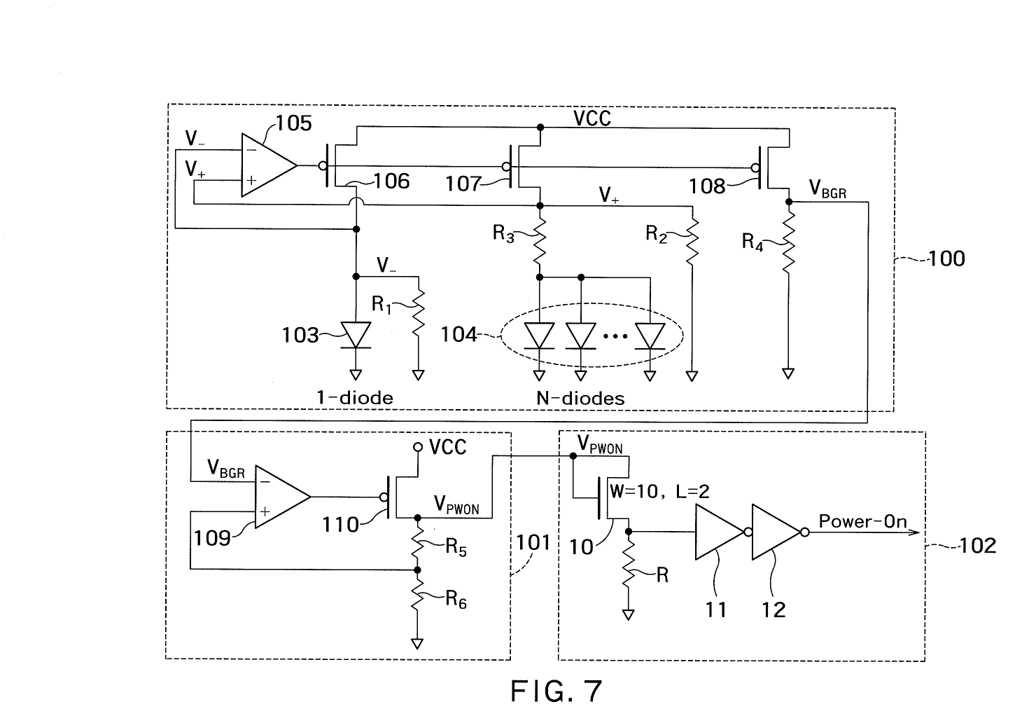

Next, the second embodiment of the present invention will be described with reference to FIGS. 5 and 6. In particular, as can be seen from FIG. 5, the second embodiment gives a circuit configuration in which the drain side of the diode-connected NMOS transistor 30 in the first embodiment of FIG. 3 is connected to a power supply voltage VDD via a depletion type (D-type) NMOS transistor 50 (voltage drop circuit). As the gate voltage of the D-type NMOS transistor 50, the power supply voltage VDD is applied. The other circuit configurations are the same as those in the first embodiment of FIG. 3, and identical reference numerals are given to the similar components, to omit repetitive description on them.

Furthermore, FIG. 6 is a graph showing the VG-ID characteristics with respect to three varying mobilities (high, medium, and low mobilities) of the diode-connected NMOS transistor 30.

In the first embodiment and the present embodiment, the intensity of a source-drain electric field becomes high so that the dependency of the mobilities on the drain-source potential difference may influence the VG-ID characteristic. Accordingly, variations of this dependency may cause the operating point to fluctuate as shown in FIG. 6, which may move the point where the effect of decreasing the threshold voltage and the effect of decreasing the mobilities owing to a rise in temperature are canceled out by each other.

Accordingly, the present embodiment intends to interpose the D-type NMOS transistor 50 between the external power supply VDD and the diode-connected NMOS transistor 30 so that the source-drain electric field may be relaxed, thereby suppressing the influence of fluctuations in dependency of the mobilities on the source-drain electric field.

As described above, according to the present embodiment, it is possible to detect a constant power supply voltage irrespective of variations in dependency of the mobilities on the source-drain electric field.

Next, before describing a third embodiment of the present invention, a BGR voltage detection circuit of a second comparison example the present inventor et al. perceive will be described.

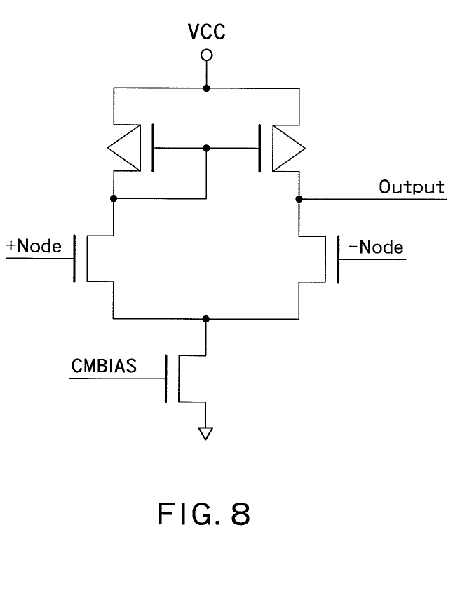

FIG. 7 shows the BGR voltage detection circuit of the second comparison example. Further, FIG. 8 shows one example of a specific circuit configuration of an operational amplifier which is used in FIG. 7.

In the BGR voltage detection circuit of the second comparison example, a BGR voltage (V_{BGR}) output from a BGR circuit 100 is received by an operational amplifier 109 to be multiplied by a numeric constant and output as the power supply voltage of the diode-connected NMOS transistor 10 in a voltage detection circuit 102, thereby detecting whether the BGR circuit 100 is providing a sufficient voltage desired.

It has been found that in the BGR voltage detection circuit of the second comparison example, the BGR voltage has no temperature dependency and so the potential obtained by multiplying this BGR voltage by the numeric constant has no temperature dependency either. Accordingly, in the above BGR voltage detection circuit using the numeric multiple of the BGR voltage as its power supply, this constant must be set to a large value in order to detect the potential even in the case of a high threshold voltage due to a low temperature, which is disadvantageous in low-voltage operations.

### Third Embodiment

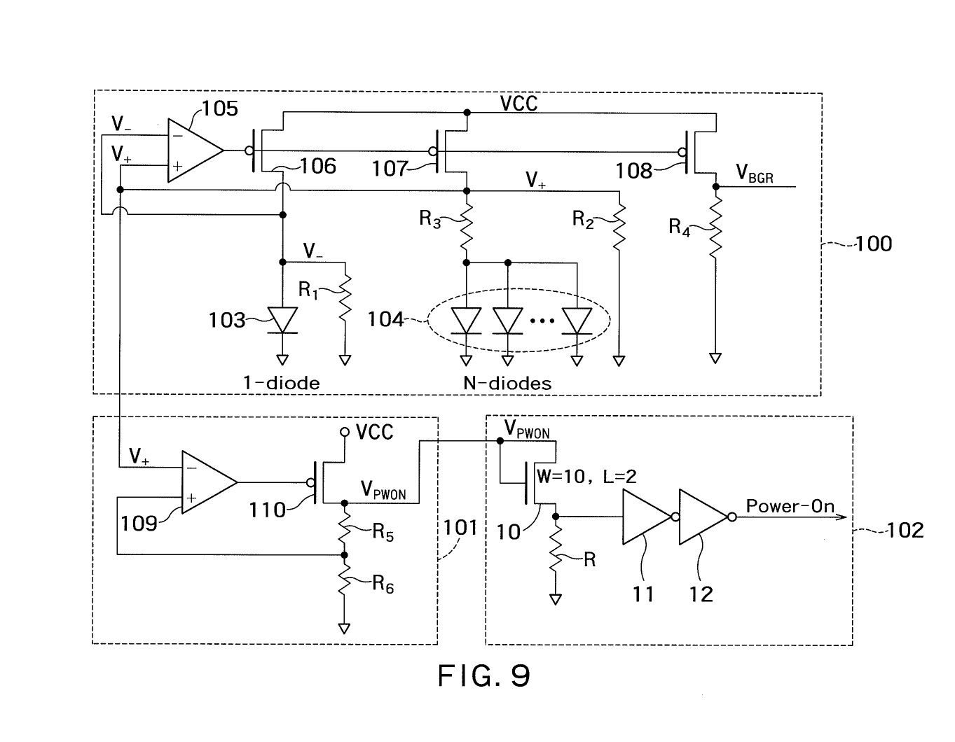

Next, a BGR voltage detection circuit according to the third embodiment of the present invention will be described with reference to FIG. 9. The third embodiment provides a circuit in which it is unnecessary to set the above constant to a large value in order to be capable of detecting the voltage even in the case of a high threshold voltage due to a low temperature. In contrast to the second comparison example, in the BGR voltage detection circuit of FIG. 9, the potential of a node of diodes 104 and a resistor R₃ which are connected in series is multiplied by a numeric constant and output as the power supply voltage of the above diode-connected NMOS transistor 10, thereby enabling detecting whether the BGR circuit 100 is providing a sufficient voltage desired.

Thus, in the present embodiment, the potential V₊of the node on the upstream side of the series connection of the resistor R₃ and the diodes 104, which have almost the same temperature dependency as the above diode-connected NMOS transistor 10, is multiplied by the constant and input to the above BGR voltage detection circuit. This eliminates the necessity of setting this constant to a large value even in the case of the high threshold voltage due to the low temperature, thus being advantageous in low-voltage operations.

As described above, according to the present embodiment, it is possible to obtain a BGR voltage detection circuit which is advantageous in low-voltage operations.

It is to be noted that this BGR circuit 100, a buffer circuit 101, and a voltage detection circuit 102 have the following circuit configuration.

The BGR circuit 100 includes an operational amplifier 105. An output terminal of the operational amplifier 105 is connected to the respective gates of PMOS transistors 106, 107, and 108, each of which is supplied with a power supply voltage VCC at its one end. The other end of the PMOS transistor 106 is connected to a ground potential via a resistor R₁ and a diode 103 which are connected in parallel. The other end of the PMOS transistor 107 is connected to the ground potential via the resistor R₃ and the N number of parallel-connected diodes 104. Further, the other end of the PMOS transistor 107 is connected to the ground potential via a resistor R₂. The other end of the PMOS transistor 108 is connected to the ground potential via the resistor R₄. A node between the PMOS transistor 108 and the resistor R₄ provides an output terminal for outputting the BGR voltage. To an inverting input terminal of this operational amplifier 105, the other end (V₋) of the PMOS transistor 106 is connected, and to a non-inverting input terminal thereof, the other end (V₊) of the PMOS transistor 107 is connected.

Further, the above buffer circuit 101 includes an operational amplifier 109. To an inverting input terminal of the operational amplifier 109, the other end (V₊) of the PMOS transistor 107 is connected. An output terminal of the operational amplifier 109 is connected to the gate of a PMOS transistor 110, which is supplied with the power supply voltage VCC at its one end. The other end of the PMOS transistor 110 is connected to the ground potential via resistors R₅ and R₆. A node between the resistors R₅ and R₆ is connected to a non-inverting input terminal of the operational amplifier 109.

Further, to the gate and drain of the diode-connected NMOS transistor 10 in the voltage detection circuit 102, the other end (power-on output voltage: V_{PWON}) of the PMOS transistor 110 in the above buffer circuit 101 is connected. The connections among the NMOS transistor 10, resistor R, and inverters 11 and 12 are the same as those of FIG. 1, and repetitive description on them will be omitted.

The other end (V₋) of the above PMOS transistor 106 may be connected to the inverting input terminal of the operational amplifier 109.

Although the embodiments of the present invention have been described in detail, the specific constitution is not limited to these embodiments and can be modified variously without departing the gist of the present invention.

For example, the NMOS transistor 30 may be a diode-connected PMOS transistor.

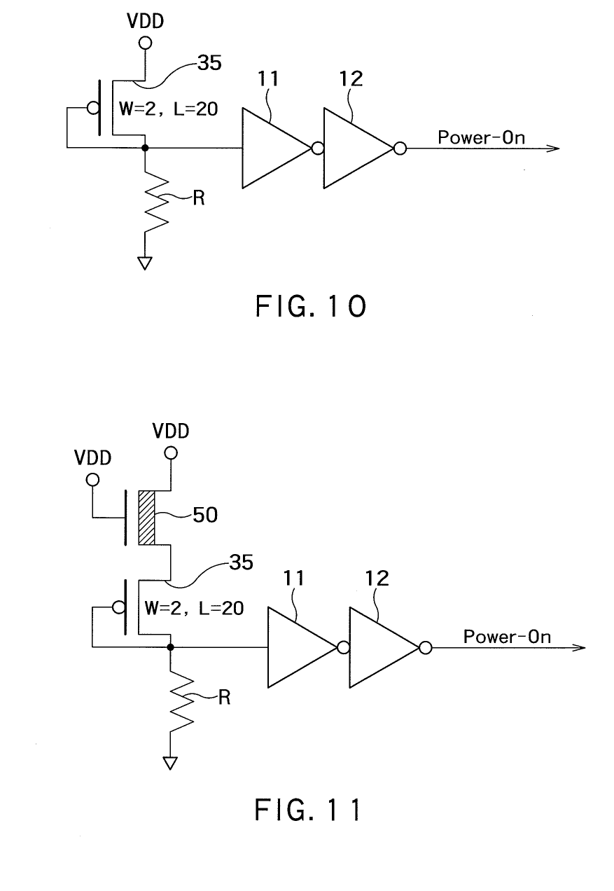

That is, as a modification of the first embodiment, such a constitution may be employed that, as shown in FIG. 10, the drain and the gate of a PMOS transistor are diode-connected, the power supply voltage VDD is connected to its source side, and the drain side is grounded via a current-limiting resistor R so that a potential of the drain might be received by the inverters 11 and 12 (drain voltage detection circuit). Thus, this modification will function in the same way as the first embodiment. Further, as a modification of the second embodiment, such a constitution may be employed that, as shown in FIG. 11, a D-type NMOS transistor 50 may be interposed between the power supply voltage VDD and the source of the PMOS transistor in the circuit of FIG. 10. Thus, this modification will function in the same way as the second embodiment.

1. A voltage detection circuit comprising:
a negative-channel metal-oxide-semiconductor field-effect transistor (NMOS transistor) diode-connected, a gate and a drain of the NMOS transistor configured to receive a power supply voltage;
a resistor connected between a source of the NMOS transistor and a ground potential; and
a source voltage detection circuit configured to receive a voltage of the source,
wherein a channel width and a channel length of the NMOS transistor are set in such a manner that a drain current of the NMOS transistor is substantially constant in gate voltage-drain current characteristics (a VG-ID curve) of the NMOS transistor regardless of the surrounding temperature.

2. The voltage detection circuit of claim 1, wherein a voltage drop circuit is connected between the drain of the NMOS transistor and the power supply voltage.

3. The voltage detection circuit of claim 2, wherein the voltage drop circuit is a depletion-type (D-type) NMOS transistor.

4. The voltage detection circuit of claim 3, wherein a gate of the D-type NMOS transistor is configured to receive the power supply voltage.

5. The voltage detection circuit of claim 1, wherein the source voltage detection circuit is an inverter circuit.

6. A voltage detection circuit comprising:
a positive-channel metal-oxide-semiconductor field-effect transistor (PMOS transistor) diode-connected, a source of the PMOS transistor configured to receive a power supply voltage;
a resistor connected between a drain of the PMOS transistor and a ground potential; and
a drain voltage detection circuit is configured to receive a voltage of the drain,
wherein a channel width and a channel length of the PMOS transistor are set in such a manner that a drain current of the PMOS type transistor is substantially constant in a VG-ID curve of the PMOS transistor regardless of the surrounding temperature.

7. The voltage detection circuit of claim 6, wherein a voltage drop circuit is connected between the source of the PMOS transistor and the power supply voltage.

8. The voltage detection circuit of claim 7, wherein the voltage drop circuit is a D-type NMOS transistor.

9. The voltage detection circuit of claim 8, wherein a gate of the D-type NMOS transistor is configured to receive the power supply voltage.

10. The voltage detection circuit of claim 6, wherein the drain voltage detection circuit is an inverter circuit.

11. A BGR voltage detection circuit comprising:
a reference voltage generation circuit comprising:
a first diode connected between a first node and a ground potential;
a first resistor connected between the first node and the ground potential;
a second resistor, a first end of the second resistor being connected to a second node;
a plurality of second diodes connected in parallel, each second diode comprising a first end connected to a second end of the second resistor and a second end connected to the ground potential;
a third resistor connected between the second node and the ground potential;
a first PMOS transistor connected between the first node and a power supply voltage;
a second PMOS transistor connected between the second node and the power supply voltage;
a third PMOS transistor connected between a third node and the power supply voltage;
a fourth resistor connected between the third node and the ground potential; and
a first amplifier circuit, comprising an inverting input terminal configured to receive a voltage of the first node, a non-inverting terminal configured to receive a voltage of the second node, and an output terminal connected to the gates of the first, second, and third PMOS transistors,
wherein a voltage of the third node is a BGR voltage;
a second amplifier circuit is configured to output a power-on output voltage by amplifying the voltage of the first node or the second node;
an NMOS transistor diode-connected, a gate and a drain of the NMOS transistor configured to receive the power-on output voltage;
a fifth resistor connected between a source of the NMOS transistor and the ground potential; and
a source voltage detection circuit configured to receive a voltage of the source of the NMOS transistor.

12. The BGR voltage detection circuit of claim 11, wherein the second amplifier circuit comprises:
a fourth PMOS transistor, a source of the fourth PMOS transistor is configured to receive the power supply voltage and a drain of the fourth PMOS transistor is configured to output the power-on output voltage;
a sixth resistor comprising a first end connected to the drain of the fourth PMOS transistor;
a seventh resistor comprising a first end connected to a second end of the sixth resistor, and a second end connected to the ground potential; and
a third amplifier circuit comprising an inverting input terminal configured to receive the voltage of the first node or of the second node, a non-inverting input terminal connected to a node between the sixth resistor and the seventh resistor, and an output terminal connected to a gate of the fourth PMOS transistor.

13. The BGR voltage detection circuit of claim 11, wherein the source voltage detection circuit is an inverter circuit.
